(19) United States
(12) Patent Application Publication
(10) Pub. No.: US 2023/0291179 A1
(43) Pub. Date: Sep. 14, 2023

(54) DFB LASER MANUFACTURING METHOD BASED ON DIELECTRIC LATERALLY COUPLED GRATING WITH DETERMINISTIC GRATING COUPLING COEFFICIENT

(71) Applicant: SUN YAT-SEN UNIVERSITY, Guangdong (CN)

(72) Inventors: Ying YU, Guangdong (CN); Zhuohui YANG, Guangdong (CN); Lin LIU, Guangdong (CN); Siyuan YU, Guangdong (CN)

(73) Assignee: SUN YAT-SEN UNIVERSITY, Guangdong (CN)

(21) Appl. No.: 18/318,728

(22) Filed: May 17, 2023

Related U.S. Application Data
(63) Continuation of application No. PCT/CN2022/087169, filed on Apr. 15, 2022.

(30) Foreign Application Priority Data
Sep. 15, 2021 (CN) 202111083202.3

(51) Int. Cl. H01S 5/12

(52) U.S. Cl. CPC H01S 5/1237; H01S 5/1231

(57) ABSTRACT

The present invention discloses DFB laser manufacturing method based on dielectric laterally coupled grating with deterministic grating coupling coefficient, comprising: S1: performing photolithography on an epitaxial substrate of the laser without an etch-stop layer to obtain a photoresist pattern with a waveguide morphology in a predetermined geometric configuration, and then performing dry etching and removing the photoresist to obtain a substrate of a waveguide structure in the predetermined geometric configuration; S2: depositing a layer of an insulating film with a low refractive index on the substrate; S3: depositing a dielectric film with a high refractive index on the insulating film; S4: performing photolithography on the dielectric film to prepare a photoresist pattern as a laterally coupled grating morphology; S5: performing etching and removing the photoresist for the dielectric film on the photoresist pattern to prepare a dielectric laterally coupled grating for the laser, and to further prepare a DFB laser.

### CROSS-REFERENCE TO RELATED APPLICATION

This application is a continuation of international application of PCT application serial no. PCT/CN2022/087169, filed on Apr. 15, 2022, which claims the priority benefits of China application no. 202111083202.3, filed on Sep. 15, 2021. The entirety of the above-mentioned patent application is hereby incorporated by reference herein and made a part of this specification.

### BACKGROUND

### Technical Field

The present invention relates to the technical field of semiconductors, and in particular to a DFB laser manufacturing method based on a dielectric laterally coupled grating with a deterministic grating coupling coefficient.

### Description of Related Art

The distributed feedback (DFB) laser in traditional industrial batches is typically produced by firstly preparing the grating near the active region and then epitaxially regrowth the cladding layer and contact layer. However, this method has a drawback: once the grating is completed, the wavelength and interval of the laser cannot be adjusted freely. Additionally, the regrowth process can introduce defects that leads to non-radiative recombination and carrier leakage, ultimately reducing the laser's performance. An alternative, regrowth-free approach is using Bragg gratings etched alongside a ridge waveguide to form a laterally coupled distributed-feedback (LC-DFB) laser. This type of laterally coupled (LC) grating can be fine-tuned to taking full account of the characteristics of epitaxial materials, and can establish multiple types of grating-based semiconductor lasers (including DFB, DBR and tunable lasers) or multi-wavelengths single-mode operated laser array on the same platform. This approach can significantly reduce the packaging size and cost of multi-wavelengths single-mode operated laser array, improve packaging accuracy, and facilitate applications that require precise alignment of laser output, such as optical modules.

Traditionally, the LC gratings are fabricated simultaneously during the waveguide etching process, that is, using one-step reactive ion etching (RIE) approach. However, due to local chemical transportation and reaction rate variations caused by the etched ridge and the very narrow grating gaps, it is very difficult to control the etch depth at the foot of the ridge waveguide where the grating intercepts the optical mode. An undesirable feature known as ‘footing’ (about 200-300 nm), which is a gradual increase of etch depth away from the foot of the etched waveguide, and another feature known as ‘RIE-lag’, which is a decreased etch depth in narrow gaps, result in significant uncertainties in the grating coupling coefficient κ value.

To achieve high-performance single-mode operation with proper feedback strength, stringent requirement is raised on the etching depth. Inadequate etching depth results in weak feedback strength, compromising the single-mode characteristics of the device. While excessive etching depth leads to an extension of the etched interface into the active layer region due to footing, generating a profusion of surface states and defects. These phenomena culminate in an amplified threshold, reduced power output, and mode hopping.

Alternatively, the trapezoidal ridge waveguide offers a solution by enabling adjustment of the sidewall slope/sidewall angle from 90° to 60-85°, minimizing the footing to below 100 nm, and affording precise control of the etching depth. This optimization improves the morphology of the laterally coupled grating and facilitates the accurate regulation and control of the grating feedback strength.

Furthermore, an approach for preparing LC gratings is developed using a metal grating. This technique primarily involves exposing the photoresist pattern of the grating, followed by vaporizing the metal and finally peeling it from the photoresist. However, for dense and fine first-order gratings with a grating feature width of approximately 100 nm, the peeling process of metal gratings is often challenging, resulting in poor process stability and high defective rates. Moreover, metal gratings exhibit relatively strong light absorption, which increases the threshold, decreases output power, and reduces slope efficiency.

In the prior art, a Chinese invention patent with publication No. CN108808442A, published on 13 Nov. 2018, discloses a method for preparing a multi-wavelength distributed feedback semiconductor laser array. The laser array includes a laterally coupled grating as the grating, a ridge waveguide as the waveguide, and an etched surface as the output optical cavity surface. While the disclosed solution deals with distributed feedback semiconductor lasers, it addresses the following issues: susceptibility of existing laterally coupled surface grating DFB laser arrays to FP longitudinal mode resonant cavity interference, weak capacity for longitudinal mode selection, and difficulty in balancing wavelength control accuracy, low cost, and consistency of transverse mode distribution. However, the solution does not address the optimization of grating design and process for deterministic coupling coefficient.

### SUMMARY

The present invention proposes a DFB laser manufacturing method based on a dielectric laterally coupled grating with a deterministic grating coupling coefficient. This method addresses the limitations of existing DFB laser array designs, which lack flexibility in achieving a DFB laser with a deterministic grating coupling coefficient.

The primary purpose of the present invention is to solve the above technical problems, and the technical solution of the present invention is as follows.

A DFB laser manufacturing method based on a dielectric laterally coupled grating with a deterministic grating coupling coefficient, comprising the steps of:
S1: performing photolithography on an epitaxial substrate of the laser without an etch-stop layer to obtain a photoresist pattern with a waveguide morphology in a pre-determined geometric configuration. Subsequently, performing dry etching and removing the photoresist to obtain a substrate of a waveguide structure in the predetermined geometric configuration;
S2: depositing a layer of an insulating film with a low refractive index on the substrate obtained in the step S1.
S3: depositing a dielectric film with a high refractive index on the layer of the insulating film;
S4: performing photolithography on the dielectric film to prepare a photoresist pattern with a laterally coupled grating morphology;
S5: performing etching and removing the photoresist for the dielectric film on the photoresist pattern obtained in the step S4 to prepare a dielectric laterally coupled grating for the laser, and using the dielectric laterally coupled grating to prepare a DFB laser.

Specifically, the epitaxial substrate refers a substrate with an epitaxial structure.

Further, the present invention provides a method for fabricating a zero-footing substrate of the waveguide structure with a predetermined geometric configuration, which enables improved corner footing with a height of less than 100 nm and a more accurate estimation of the grating coupling coefficient. Specifically, the method involves performing dry etching and removing the photoresist in the predetermined geometric configuration, which is a positive trapezoid with an inner angle of 60° to 85°. The resulting waveguide structure features a positive trapezoid geometry that is uniquely suited for the described applications.

Further, a specific process of the step S1 comprises:
performing photolithography on the epitaxial substrate of the laser without the etch-stop layer to obtain a photoresist pattern with the waveguide morphology in the predetermined geometric configuration, which is controlled through an exposure process or post-processing method. The photoresist pattern is then used as a mask for dry etching, after which the photoresist is removed to yield the desired zero-footing substrate of the waveguide structure in the predetermined geometric configuration.

Further, the epitaxial laser structure without the etch-stop layer in the step S1 comprises GaAs-based, GaSb-based and GaN laser materials.

Further, the angle of the photoresist pattern with the waveguide morphology in the predetermined geometric configuration, which ranges from 60° to 80°, can be obtained through careful manipulation of exposure process parameters and post-processing methods such as exposure dose, developing time, post-baking reflow, or plasma dry processing.

Further, the process parameters of the dry etching in step S1 are carefully adjusted to achieve the desired waveguide structure geometry and size, including gas flow rate, pressure, plasma concentration, bias pressure, and sample temperature.

Further, in step S2, an insulating film with a thickness of less than 50 nm is deposited onto the waveguide structure. The insulating film is composed of a dielectric material with a low refractive index, which is less than 2.

Further, in step S3, a dielectric film with a thickness of less than 300 nm is deposited onto the insulating film. The deposited film is made of a high refractive index dielectric material, which has a refractive index greater than 2.

Further, in step S4, the grating design is adjusted to optimize the grating period, duty cycle, grating length, and especially the grating size at the position of ridge waveguide. The exposure process is debugged by optimizing the overall exposure dose and locally optimizing the dose for optimal performance.

Further, in step S5, a dielectric laterally coupled grating is prepared, which is either a first-order or third-order grating.

Compared with the prior art, the technical solution of the present invention has the following advantages:

By incorporating dielectric laterally coupled gratings, the present invention avoids the complexity and contamination risks associated with traditionally buried structure gratings that require secondary epitaxy. Furthermore, this approach enhances the flexibility of DFB laser array design, facilitates the utilization of epitaxial wafers, enables multi-wavelength arrays, and enables high repeatability preparation of epitaxial material laterally coupled gratings for lasers without etched cut-off layers.

The novel grating structure also affords accurate and deterministic grating coupling coefficient κ that can be engineered independent of the laser material epitaxy process. The scheme can therefore be readily implemented on other material systems such as InP-, GaAs/Si- and GaSb-based compound semiconductor lasers, and in other wavelength windows by scaling the size of the grating. The simplicity and versatility of the regrowth-free scheme makes it possible to establish a new paradigm of semiconductor laser manufacturing in which the co-manufacturing, on the same fabrication platform, of multiple types of grating-based semiconductor lasers (including DFB, DBR and tunable lasers) very different in their active materials and operating wavelengths would potentially reduce their manufacturing cost very significantly.

### BRIEF DESCRIPTION OF DRAWINGS

FIG. 1 is a schematic diagram of the structure of the LC-DFB laser with a deterministic grating coupling coefficient of the present invention.

FIG. 2 is a flow chart of a LC-DFB laser manufacturing method based on a deterministic grating coupling coefficient of a dielectric laterally coupled grating of the present invention.

FIG. 3 is the SEM diagram of a low-footing and positive trapezoid tilted waveguide structure covered with photoresist of an embodiment of the present invention.

FIG. 4 is the SEM diagram of a photoresist pattern with a laterally coupled grating morphology of an embodiment of the present invention.

FIG. 5 is the SEM diagram of the structure of a DFB laser dielectric grating (take amorphous silicon for example) obtained by an embodiment of the present invention.

### DETAILED DESCRIPTION OF EMBODIMENTS

To facilitate a more comprehensive comprehension of the aforementioned objectives, characteristics, and benefits of the present invention, the invention is elaborated further below in conjunction with the associated drawings and specific examples. It is noteworthy that the embodiments and features disclosed in this application may be integrated with one another as long as there is no contradiction between them.

Although many specific details are set forth in the following description in order to facilitate a full understanding of the invention, the invention may also be implemented in other ways than those described herein, and therefore the scope of protection of the invention is not limited by the specific embodiments disclosed below.

### Embodiment 1

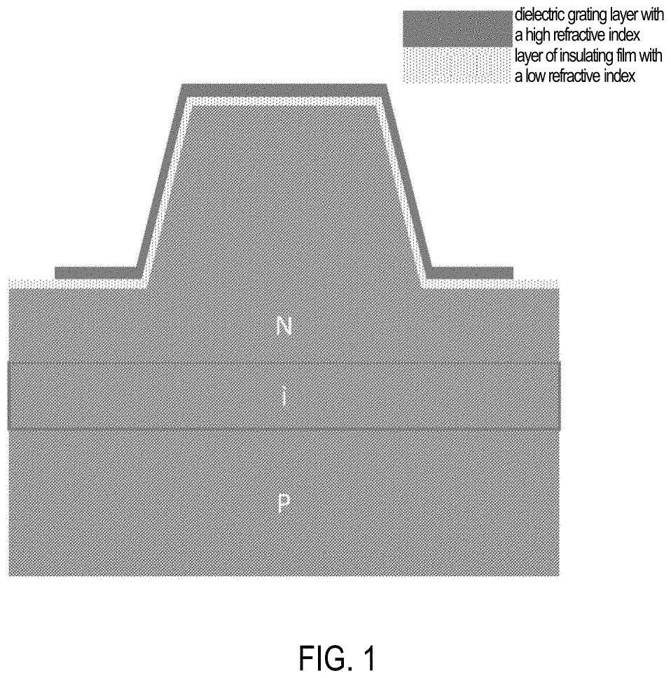

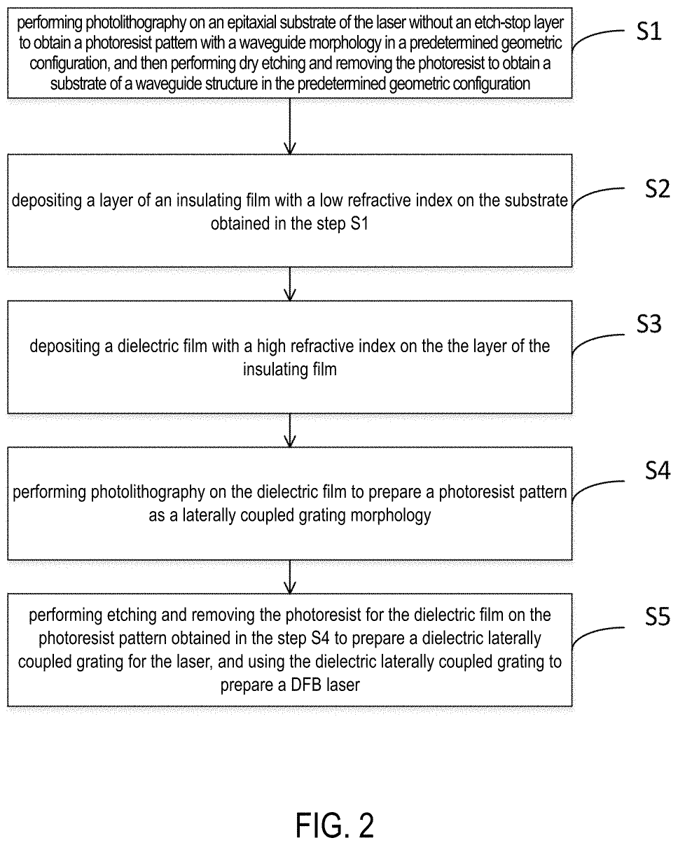

As shown in FIG. 1, a DFB laser manufacturing method based on a deterministic grating coupling coefficient of a dielectric laterally coupled grating, comprising the following steps:

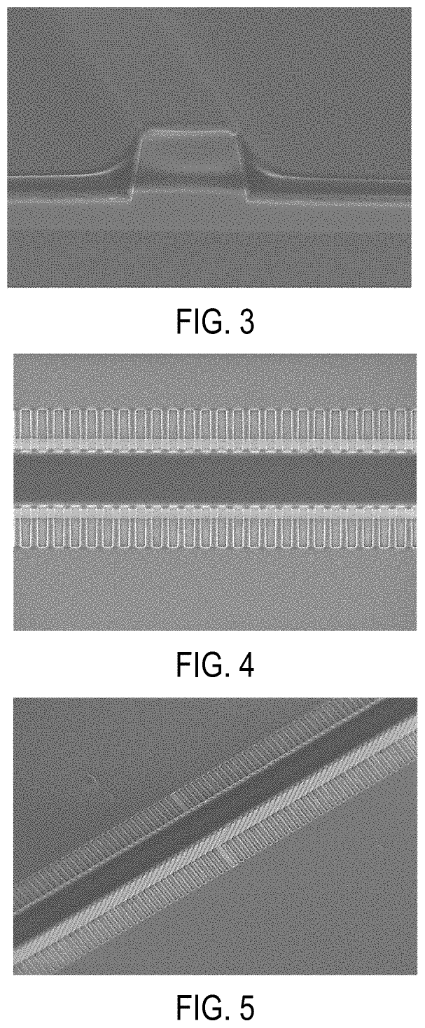

S1: performing photolithography on an epitaxial substrate of the laser without an etch-stop layer to obtain a photoresist pattern with a waveguide morphology in a predetermined geometric configuration. The photoresist pattern is then used as a mask for dry etching, which removes the unprotected regions of the substrate, resulting in a substrate of a waveguide structure in the predetermined geometric configuration, as illustrated in FIG. 3.

It should be noted that in a specific embodiment, the predetermined geometric configuration of the waveguide can be a positive trapezoid. The process involves photolithography on the epitaxial substrate of the laser without the etch-stop layer to obtain a photoresist pattern with a waveguide morphology in a positive trapezoid configuration by controlling the exposure process or post-processing method. Then, dry etching is performed to remove the photoresist and obtain a zero-footing substrate of the waveguide structure in the predetermined geometric configuration with a determinable size. This zero-footing waveguide structure can be used for accurate estimation of the grating coupling coefficient of the DFB laser, as depicted in FIG. 3.

It should be noted that the zero-footing waveguide structure is obtained by designing the waveguide structure with a positive trapezoid configuration. The determinable size of the zero-footing waveguide structure facilitates accurate estimation of the grating coupling coefficient of the DFB laser and enables the determination of the interaction of the grating with the optical field in the active region.

The epitaxial substrate of the laser without the etch-stop layer in step S1 includes GaAs-based, GaSb-based and GaN laser materials. The etching cannot be accurately stopped over the active region in etching due to the presence of Al elements in the separate confinement layer.

Further, the angle of the photoresist pattern with the waveguide morphology in the predetermined geometric configuration is ranged from 60° to 80°, and controlling exposure process parameters and post-processing methods including exposure dose, developing time, post-baking reflow or plasma dry processing.

The waveguide structure for the substrate of the waveguide structure in the predetermined geometric configuration has the positive trapezoid with an inner angle of 60° to 85°, and the inner angle is favorable for corner footing with a height of less than 100 nm while facilitating a more accurate estimation of the grating coupling coefficient.

Further, process parameters of the dry etching comprise process gas flow rate, pressure, plasma concentration, bias pressure magnitude or sample temperature.

S2: a layer of an insulating film with a low refractive index is deposited on the substrate obtained in the step S1.

It should be noted that the insulating film deposited in this step has a thickness of less than 50 mm and consists of a low refractive index dielectric material (n<2, where n is the refractive index of the low refractive index dielectric material). This facilitates the coupling of the grating with the optical field in the active region and enables easier refractive index modulation.

S3: a dielectric film with a high refractive index is deposited on the layer of the insulating film.

It should be noted that the dielectric film deposited in the step S3 has a thickness of less than 300 mm. The deposited dielectric film is a high refractive index dielectric material, such as amorphous silicon, silicon nitride rich, etc. And the dielectric material with the high refractive index has a refractive index of greater than 2.

The present invention improves the preparation accuracy of the process and circumvents the absorption loss introduced by the metal grating, through the introduction of high refractive index dielectric materials (such as amorphous silicon, silicon nitride rich, etc.).

S4: photolithography is performed on the dielectric film to prepare a photoresist pattern with a laterally coupled grating morphology, as shown in FIG. 4.

The grating design includes correction of the grating period, duty cycle, grating length, and ridge waveguide position grating size. Debugging exposure process comprises overall exposure dose debugging and local dose optimization.

S5: etching and removing the photoresist for the dielectric film are performed on the photoresist pattern obtained in the step S4 to prepare a dielectric laterally coupled grating for the laser, and using the dielectric laterally coupled grating to prepare a DFB laser, as shown in FIG. 5.

The amorphous silicon grating prepared in step S5 is a first-order or third-order grating. Since the size of the waveguide can be determined, the size of the dielectric grating can be determined, so that the laser device with a deterministic grating coupling coefficient can be prepared. In one specific embodiment, the obtained dielectric laterally coupled grating can be used to prepare the DFB laser by using the existing process flow. The existing process flow includes planarization, P-type electrode preparation, substrate thinning, N-type electrode preparation, and annealing to form ohmic contacts.

The dielectric laterally coupled grating proposed by the invention is formed by etching, which can obtain high-quality, fine and stable first-order and third-order gratings and can achieve ultra-small grating period intervals (adjacent wavelength grating feature size is less than 2 nm).

The invention realizes the high repeatability preparation of laterally coupled gratings of laser epitaxial materials (GaAs, GaSb, GaN-based) without the etch-stop layer, and realizes DFB lasers with deterministic grating coupling coefficients, which further improves the flexibility of DFB laser array design and facilitates the utilization of epitaxial wafers and the realization of multi-wavelength arrays.

Obviously, the above embodiments of the present invention are only for the purpose of clearly explaining the examples of the present invention, but not for the purpose of limiting the protection scope of the present invention. For those skilled in the art, other changes or variations in different forms can be made on the basis of the above description. It is unnecessary and impossible to enumerate all the implementation methods here. Any modification, equivalent substitution or improvement made within the spirit and principle of the invention shall fall within the protection scope of the claims of the present invention. cm What is claimed is:

1. A DFB laser manufacturing method based on a dielectric laterally coupled grating with a deterministic grating coupling coefficient, wherein the DFB laser manufacturing method comprises steps of:
S1: performing photolithography on an epitaxial substrate of a laser without an etch-stop layer to obtain a photoresist pattern with a waveguide morphology in a predetermined geometric configuration, and then performing dry etching and removing a photoresist to obtain a substrate of a waveguide structure in the predetermined geometric configuration;
S2: depositing a layer of an insulating film with a low refractive index on the substrate obtained in the step S1;
S3: depositing a dielectric film with a high refractive index on the layer of the insulating film;
S4: performing photolithography on the dielectric film to prepare a photoresist pattern with a laterally coupled grating morphology;
S5: performing etching and removing the photoresist for the dielectric film on the photoresist pattern obtained in the step S4 to prepare a dielectric laterally coupled grating for the laser, and using the dielectric laterally coupled grating to prepare a DFB laser.

2. The DFB laser manufacturing method based on the dielectric laterally coupled grating with the deterministic grating coupling coefficient according to claim 1, wherein the substrate of the waveguide structure in the predetermined geometric configuration obtained in the step S1 by performing dry etching and removing the photoresist is a zero-footing substrate of the waveguide structure with a deterministic geometry size, the predetermined geometric configuration is a positive trapezoid, the waveguide structure for the substrate of the waveguide structure in the predetermined geometric configuration has the positive trapezoid with an inner angle of 60° to 85°, the inner angle being favorable for a footing with a height of less than 100 nm.

3. The DFB laser manufacturing method based on the dielectric laterally coupled grating with the deterministic grating coupling coefficient according to claim 1, wherein a specific process of the step S1 comprises:
performing photolithography on the epitaxial substrate of the laser without the etch-stop layer, and obtaining the photoresist pattern with the waveguide morphology in the predetermined geometric configuration by controlling exposure process or post-processing method, and then performing dry etching and removing the photoresist to obtain a zero-footing substrate of the waveguide structure in the predetermined geometric configuration with a determinable size.

4. The DFB laser manufacturing method based on the dielectric laterally coupled grating with the deterministic grating coupling coefficient according to claim 1, wherein the laser epitaxial substrate without the etch-stop layer in the step S1 comprises GaAs-based, GaSb-based and GaN laser materials.

5. The DFB laser manufacturing method based on the dielectric laterally coupled grating with the deterministic grating coupling coefficient according to claim 1, wherein an angle of the photoresist pattern with the waveguide morphology in the predetermined geometric configuration is ranged from 60° to 80°, and controlling exposure process parameters and post-processing methods comprises exposure dose, developing time, post-baking reflow or plasma dry processing.

6. The DFB laser manufacturing method based on the dielectric laterally coupled grating with the deterministic grating coupling coefficient according to claim 1, wherein, process parameters of the dry etching comprise process gas flow rate, pressure, plasma concentration, bias pressure or sample temperature.

7. The DFB laser manufacturing method based on the dielectric laterally coupled grating with the deterministic grating coupling coefficient according to claim 1, wherein the insulating film deposited in the step S2 has a thickness of less than 50 nm, the insulating film deposited is a dielectric material with a low refractive index, and the dielectric material with the low refractive index has a refractive index of less than 2.

8. The DFB laser manufacturing method based on the dielectric laterally coupled grating with the deterministic grating coupling coefficient according to claim 1, wherein the dielectric film deposited in the step S3 has a thickness of less than 300 mm, the deposited dielectric film is a high refractive index dielectric material, and the dielectric material with the high refractive index has a refractive index of greater than 2.

9. The DFB laser manufacturing method based on the dielectric laterally coupled grating with the deterministic grating coupling coefficient according to claim 1, wherein a grating design in the step S4 comprises correction of a grating period, duty cycle, grating length, and ridge waveguide position grating size, debugging exposure process comprises overall exposure dose debugging and local dose optimization.

10. The DFB laser manufacturing method based on the dielectric laterally coupled grating with the deterministic grating coupling coefficient according to claim 1, is wherein the dielectric laterally coupled grating prepared in the step S5 is a first-order or third-order grating.
